(19) United States
(12) Patent Application Publication
(10) Pub. No.: US 2025/0176209 A1
(43) Pub. Date: May 29, 2025

(54) SEMICONDUCTOR MEMORY DEVICE AND METHOD OF MANUFACTURING THE SAME

(71) Applicant: Samsung Electronics Co., Ltd., Suwon-si (KR)

(72) Inventors: Taejin Park, Suwon-si (KR); Yoona Jang, Suwon-si (KR); Sungsoo Yim, Suwon-si (KR)

(21) Appl. No.: 18/934,600

(22) Filed: Nov. 1, 2024

(30) Foreign Application Priority Data
Nov. 28, 2023 (KR) 10-2023-0168237

(51) Int. Cl. H01L 29/78; H10B 12/00

(52) U.S. Cl. CPC H10D 30/63; H10B 12/488; H10D 1/716

(57) ABSTRACT

A semiconductor memory device includes a memory cell area including a plurality of vertical channel transistors, an interface area surrounding the memory cell area in a plan view, a first insulating block in the interface area, the first insulating block facing the plurality of vertical channel transistors, and a second insulating block apart from the plurality of vertical channel transistors in a first horizontal direction with the first insulating block between the second insulating block and the plurality of vertical channel transistors, the second insulating block including a different material from the first insulating block.

### CROSS-REFERENCE TO RELATED APPLICATION

This application is based on and claims priority under 35 U.S.C. § 119 to Korean Patent Application No. 10-2023-0168237, filed on Nov. 28, 2023, in the Korean Intellectual Property Office, the disclosure of which is incorporated by reference herein in its entirety.

### BACKGROUND

The inventive concept relates to a semiconductor memory device, and more particularly, to a semiconductor memory device including a vertical channel transistor.

With the recent development of electronics technology, down-scaling of semiconductor devices is rapidly progressing. As a structure that facilitates the miniaturization and high integration of memory cells, a semiconductor memory device including a transistor having a vertical channel has been proposed.

### SUMMARY

The inventive concept provides a semiconductor memory device having improved reliability.

The inventive concept also provides a method of manufacturing a semiconductor memory device having improved reliability.

According to an aspect of the inventive concept, a semiconductor memory device includes a memory cell area including a plurality of vertical channel transistors, an interface area surrounding the memory cell area in a plan view, a first insulating block in the interface area, a side surface of the first insulating block facing the plurality of vertical channel transistors in a first horizontal direction, and a second insulating block apart from the plurality of vertical channel transistors in the first horizontal direction with the first insulating block between the second insulating block and the plurality of vertical channel transistors, the second insulating block including a different material from the first insulating block.

According to another aspect of the inventive concept, a semiconductor memory device includes a first interlayer structure including a plurality of conductive lines and a first interlayer insulating layer, the plurality of conductive lines extending lengthwise in a first horizontal direction and being apart from each other in a second horizontal direction perpendicular to the first horizontal direction, and the first interlayer insulating layer surrounding the plurality of conductive lines, a second interlayer structure including a plurality of contact plugs and a second interlayer insulating layer, the plurality of contact plugs being arranged at positions apart from the plurality of conductive lines in a vertical direction, and the second interlayer insulating layer surrounding the plurality of contact plugs, a plurality of vertical channel transistors including a plurality of channel structures between the first interlayer structure and the second interlayer structure, the plurality of channel structures each being in contact with one of the plurality of conductive lines and one of the plurality of contact plugs, a first insulating block including a side surface facing the plurality of vertical channel transistors in the first horizontal direction between the first interlayer structure and the second interlayer structure, and a second insulating block apart from the plurality of vertical channel transistors with the first insulating block between the second insulating block and the plurality of vertical channel transistors, the second insulating block vertically overlapping the first interlayer insulating layer and the second interlayer insulating layer.

According to another aspect of the inventive concept, a semiconductor memory device includes a substrate comprising a memory cell area and an interface area on at least one side of the memory cell area; a plurality of peripheral circuit transistors on an upper surface of the substrate; a wiring structure above the plurality of peripheral circuit transistors, the wiring structure comprising a plurality of first conductive lines, a plurality of first contact plugs, and an insulating layer surrounding the plurality of first conductive lines and the plurality of first contact plugs; a first interlayer structure comprising a plurality of second conductive lines and a first interlayer insulating layer, the plurality of second conductive lines extending lengthwise in a first horizontal direction above the wiring structure and being apart from each other in a second horizontal direction perpendicular to the first horizontal direction, and the first interlayer insulating layer surrounding the plurality of second conductive lines; a second interlayer structure comprising a plurality of second contact plugs and a second interlayer insulating layer, the plurality of second contact plugs being arranged at positions apart from the plurality of first conductive lines in a vertical direction, and the second interlayer insulating layer surrounding the plurality of second contact plugs; a plurality of vertical channel transistors comprising a plurality of channel structures between the first interlayer structure and the second interlayer structure, the plurality of channel structures each being in contact with one of the plurality of first conductive lines and one of the plurality of second contact plugs; a capacitor structure above the second interlayer structure and comprising a plurality of lower electrodes, an upper electrode, and a capacitor dielectric film, the plurality of lower electrodes respectively being above the plurality of channel structures, the upper electrode covering the plurality of lower electrodes and the second interlayer insulating layer, and the capacitor dielectric film being between the upper electrode, the plurality of lower electrodes, and the second interlayer insulating layer; a first insulating block in the interface area and facing the plurality of vertical channel transistors in the first horizontal direction between the first interlayer structure and the second interlayer structure; a second insulating block in the interface area, apart from the plurality of vertical channel transistors with the first insulating block between the second insulating block and the plurality of vertical channel transistors, the second insulating block vertically overlapping the first interlayer insulating layer and the second interlayer insulating layer; and a capacitor contact penetrating at least a portion of the insulating layer, the first interlayer insulating layer, the second insulating block, the second interlayer insulating layer, and the capacitor dielectric film, the capacitor contact being in contact with some of the plurality of first conductive lines and the upper electrode.

According to another aspect of the inventive concept, a method of manufacturing a semiconductor memory device includes providing a semiconductor substrate including a memory cell area and an interface area; forming a trench in the interface area of the semiconductor substrate; forming a first preliminary insulating layer conformally on a surface of the trench; forming a second preliminary insulating layer conformally on a surface of the first preliminary insulating layer such that a lowermost surface of the second preliminary insulating layer is at a higher vertical level than a lowermost surface of the first preliminary insulating layer, the second preliminary insulating layer comprising a different material from a material of the first preliminary insulating layer; forming a plurality of vertical channel transistors in the memory cell area of the semiconductor substrate; forming a plurality of contact plugs on an upper surface of respective vertical channel transistors of the plurality of vertical channel transistors; forming a capacitor structure on an upper surface of the plurality of contact plugs; and performing a chemical mechanical polishing process on a lowermost surface of the first preliminary insulating layer and on a lowermost surface of the plurality of vertical channel transistors to form a first insulating block and a second insulating block on the interface area of the semiconductor substrate.

### BRIEF DESCRIPTION OF THE DRAWINGS

Embodiments will be more clearly understood from the following detailed description taken in conjunction with the accompanying drawings in which:

FIG. 1 is a plan layout diagram of a semiconductor memory device according to embodiments;

FIG. 2 is an enlarged view of a region “EX1” in FIG. 1;

FIG. 3A is a cross-sectional view taken along line X1-X1′ in FIG. 2;

FIG. 3B is an enlarged view of a region “EXA” in FIG. 3A;

FIG. 4 is a perspective view of a semiconductor memory device according to some other embodiments;

FIG. 5 is a cross-sectional view of a semiconductor memory device according to some other embodiments; and

FIGS. 6A to 15 are diagrams illustrating a process sequence of a method of manufacturing a semiconductor memory device, according to embodiments, wherein FIGS. 6A, 8A, 10A, 11A, and 12A are plan layout diagrams of some components according to the process sequence of the method of manufacturing a semiconductor memory device, and FIGS. 6B, 7, 8B, 9, 10B, 11B, 12B, 13, 14, and 15 are cross-sectional views of a region corresponding to the line X1-X1′ in FIG. 2, according to the process sequence.

FIG. 16 shows a method of manufacturing a semiconductor device according to embodiments.

### DETAILED DESCRIPTION OF THE EMBODIMENTS

Hereinafter, embodiments of the inventive concept will be described in detail with reference to the accompanying drawings. The same reference numerals are used for the same components in the drawings, and redundant descriptions thereof are omitted.

As used herein, a semiconductor memory device may refer, for example, to a device such as a semiconductor chip (e.g., memory chip formed on a die), a stack of semiconductor chips, a semiconductor package including one or more semiconductor chips stacked on a package substrate, or a package-on-package device including a plurality of packages. These devices may be formed using ball grid arrays, wire bonding, through substrate vias, or other electrical connection elements, and may include memory devices such as volatile or non-volatile memory devices. Semiconductor packages may include a package substrate, one or more semiconductor chips, and an encapsulant formed on the package substrate and covering the semiconductor chips.

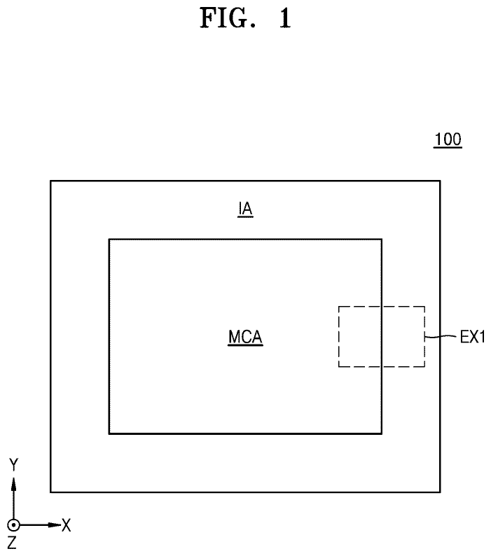

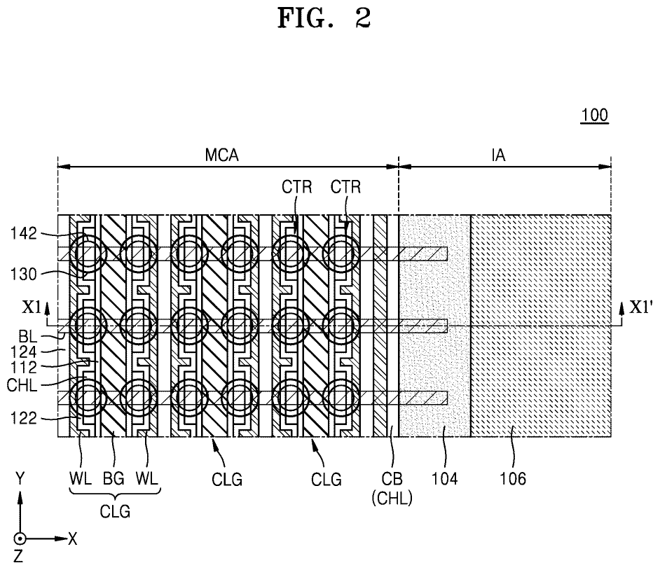

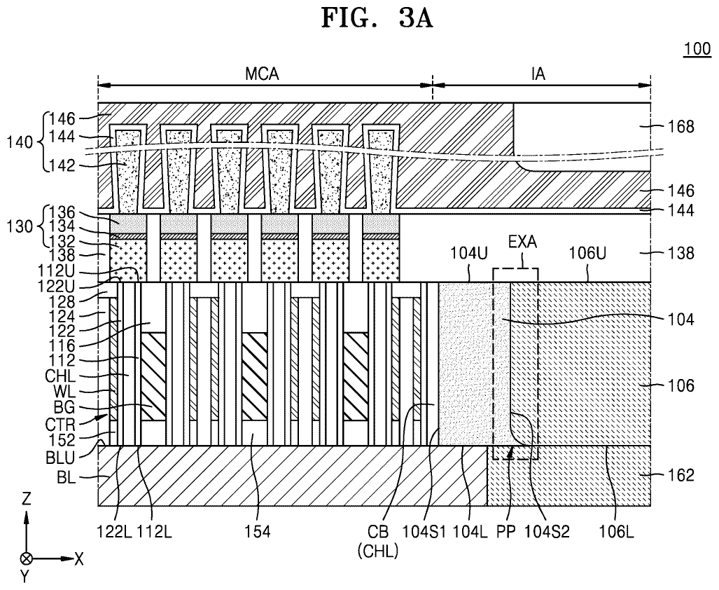

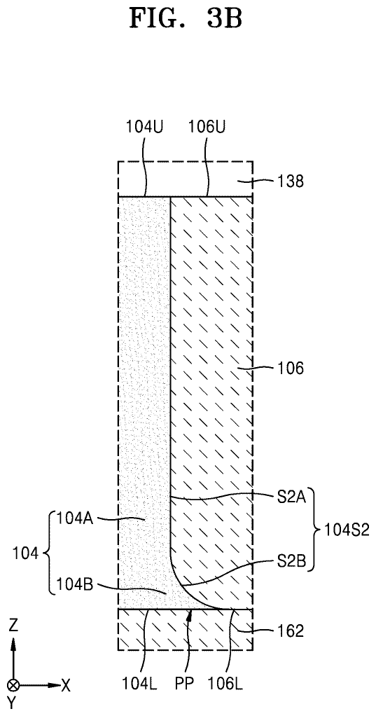

FIG. 1 is a plan layout diagram of a semiconductor memory device 100 according to embodiments. FIG. 2 is an enlarged view of a region “EX1” in FIG. 1. FIG. 3A is a cross-sectional view taken along line X1-X1′ in FIG. 2. FIG. 3B is an enlarged view of a region “EXA” in FIG. 3A.

Referring to FIGS. 1 to 3B, in a plan view, the semiconductor memory device 100 may include a memory cell area MCA, in which a plurality of memory cells are arranged, and an interface area IA surrounding the memory cell area MCA. For example, the plurality of memory cells may include a plurality of vertical channel transistors CTR. In some embodiments, the interface area IA may be an area in which contacts, vias, and wirings for electrical connection between the plurality of memory cells included in the memory cell area MCA and a peripheral circuit transistor (not illustrated) included in a peripheral circuit area (not illustrated) are formed.

In some embodiments, in a plan view, the peripheral circuit area (not illustrated) may be arranged apart from the memory cell area MCA with the interface area IA therebetween. For example, the peripheral circuit transistor (not illustrated) may be configured to transmit signals and/or power to the plurality of memory cells included in the memory cell area MCA. For example, the peripheral circuit transistor (not illustrated) may constitute various circuits, such as a command decoder, a control logic, an address buffer, a row decoder, a column decoder, a sense amplifier, and a data input/output circuit.

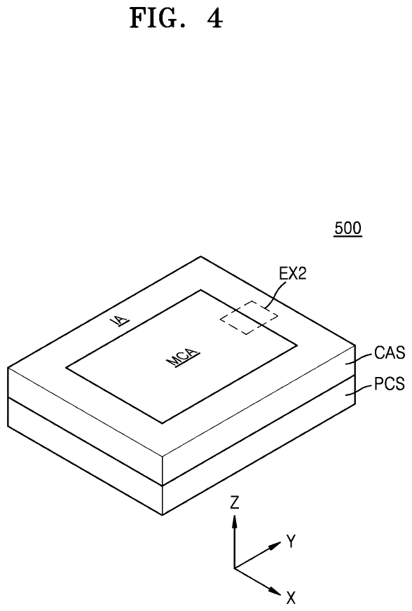

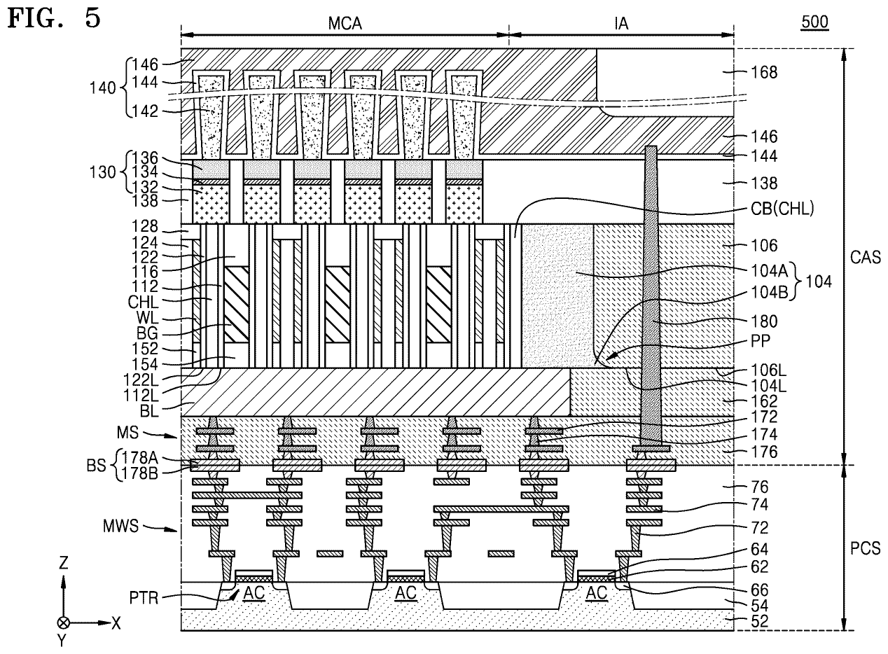

In some other embodiments, a semiconductor memory device 500 (see FIGS. 4 and 5) may have a cell on periphery (COP) structure. In this case, a cell array structure CAS (see FIGS. 4 and 5) including a plurality of memory cells and a peripheral circuit structure PCS (see FIGS. 4 and 5) including a peripheral circuit transistor PTR (see FIGS. 4 and 5) may overlap each other in a vertical direction (a Z direction). The semiconductor memory device 500 is described below.

According to embodiments, the semiconductor memory device 100 may include a plurality of conductive lines BL that extend lengthwise in a first horizontal direction (an X direction) and are repeatedly arranged apart from each other in a second horizontal direction (a Y direction) perpendicular to the first horizontal direction (the X direction). The plurality of conductive lines BL may be arranged in the memory cell area MCA and may extend to the interface area IA. For example, ends of the plurality of conductive lines BL may be arranged in the interface area IA. In the semiconductor memory device 100, each of the plurality of conductive lines BL may constitute a bit line. In some embodiments, the plurality of conductive lines BL may be apart from each other in the second horizontal direction (the Y direction) with a first interlayer insulating layer 162 therebetween. For example, the first interlayer insulating layer 162 may include a portion arranged in the memory cell area MCA and a portion arranged in the interface area IA. For example, the plurality of conductive lines BL and the first interlayer insulating layer 162 may constitute a first interlayer structure.

As used herein, an item, layer, or portion of an item or layer described as “extending” or extending “lengthwise” in a particular direction has a length in the particular direction and a width perpendicular to that direction, where the length is greater than the width.

The semiconductor memory device 100 may include, in the memory cell area MCA, a plurality of channel structures CHL arranged above the plurality of conductive lines BL and a plurality of contact plugs 130 arranged above the plurality of channel structures CHL. According to embodiments, the plurality of channel structures CHL may be repeatedly arranged apart from each other in the first horizontal direction (the X direction) and the second horizontal direction (the Y direction) above the plurality of conductive lines BL. Each of the plurality of contact plugs 130 may be arranged above the channel structure CHL corresponding thereto, among the plurality of channel structures CHL. Each of the plurality of channel structures CHL may extend in the vertical direction (the Z direction) between one of the plurality of conductive lines BL and one of the plurality of contact plugs 130.

In some embodiments, each of the plurality of conductive lines BL may be formed of or include metal, conductive metal nitride, metal silicide, doped polysilicon, or a combination thereof. For example, each of the plurality of conductive lines BL may include Ti, TiN, Ta, TaN, Mo, Ru, W, WN, Co, Ni, TiSi, TiSiN, WSi, WSiN, TaSi, TaSiN, RuTiN, CoSi, NiSi, doped polysilicon, or a combination thereof. In some embodiments, the first interlayer insulating layer 162 may be formed of or include a silicon oxide film, a silicon nitride film, or a combination thereof.

According to embodiments, each of the plurality of channel structures CHL may include a first end and a second end that are opposite to each other in the vertical direction (the Z direction). In each of the plurality of channel structures CHL, the first end may be connected to one contact plug 130 of the plurality of contact plugs 130, and the second end may be connected to one conductive line BL of the plurality of conductive lines BL. In some embodiments, the channel structure CHL may include a conductive region, for example, an impurity-doped well or an impurity-doped structure. Although not illustrated, an impurity region that functions as a source/drain region may be formed in each of the first end and the second end.

In some embodiments, each of the plurality of channel structures CHL may be formed of or include silicon, for example, single crystalline silicon, polycrystalline silicon, or amorphous silicon. In some other embodiments, each of the plurality of channel structures CHL may include at least one selected from Ge, SiGe, SiC, GaAs, InAs, and InP.

According to embodiments, the plurality of contact plugs 130 may be apart from the plurality of conductive lines BL in the vertical direction (the Z direction) with the plurality of channel structures CHL therebetween. The plurality of contact plugs 130 may be arranged in a matrix arrangement to be apart from each other in the first horizontal direction (the X direction) and the second horizontal direction (the Y direction). The plurality of contact plugs 130 may respectively correspond to and be connected to the plurality of channel structures CHL.

In some embodiments, each of the plurality of contact plugs 130 may be formed of or include metal, conductive metal nitride, metal silicide, doped polysilicon, or a combination thereof. For example, each of plurality of contact plugs 130 may include Ti, TiN, Ta, TaN, Mo, Ru, W, WN, Co, Ni, TiSi, TiSiN, WSi, WSiN, TaSi, TaSiN, RuTiN, CoSi, NiSi, doped polysilicon, or a combination thereof.

In some embodiments, as illustrated in FIG. 3A, each of the plurality of contact plugs 130 may include a first conductive pattern 132, a second conductive pattern 134, and a third conductive pattern 136, which are sequentially stacked above the plurality of channel structures CHL. For example, the first conductive pattern 132 may be formed of or include doped polysilicon, the second conductive pattern 134 may be formed of or include metal silicide, and the third conductive pattern 136 may be formed of or include metal, but embodiments are not limited thereto.

According to embodiments, the semiconductor memory device 100 may include a second interlayer insulating layer 138 surrounding the plurality of contact plugs 130. For example, the plurality of contact plugs 130 and the second interlayer insulating layer 138 may constitute a second interlayer structure. In the memory cell area MCA, each of the plurality of contact plugs 130 may penetrate the second interlayer insulating layer 138 and be in contact with one of the plurality of channel structure CHL. The plurality of contact plugs 130 may be apart from each other in a horizontal direction (the X direction and/or the Y direction) with the second interlayer insulating layer 138 therebetween. In some embodiments, the second interlayer insulating layer 138 may include a portion arranged in the interface area IA, and the portion arranged in the interface area IA may extend in the horizontal direction (the X direction and/or the Y direction) at a vertical level at which the plurality of contact plugs 130 are arranged. Herein, the term “vertical level” refers to a distance from first surfaces BLU of the plurality of conductive lines BL toward the plurality of contact plugs 130 in the Z direction and/or −Z direction.

It will be understood that when an element is referred to as “contacting” or “in contact with” another element (or using any form of the word “contact”), there are no intervening elements present at the point of contact.

In some embodiments, the second interlayer insulating layer 138 may be formed of or include a silicon oxide film, a silicon nitride film, or a combination thereof.

According to embodiments, the semiconductor memory device 100 may include, in the memory cell area MCA, a plurality of back gate electrodes BG and a plurality of word lines WL, which are respectively arranged above the plurality of conductive lines BL. Each of the plurality of back gate electrodes BG and the plurality of word lines WL may extend lengthwise in the second horizontal direction (the Y direction) between the plurality of conductive lines BL and the plurality of contact plugs 130. The plurality of back gate electrodes BG may be apart from each other in the first horizontal direction (the X direction), and the plurality of word lines WL may be apart from each other in the first horizontal direction (the X direction). According to embodiments, a pair of word lines WL of the plurality of word lines WL may be interposed between two adjacent back gate electrodes BG of the plurality of back gate electrodes. According to embodiments, a first back gate electrode BG among the plurality of back gate electrodes BG and two word lines WL that are arranged adjacent to the first back gate electrode BG and apart from each other in the first horizontal (X direction) with the first back gate electrode BG therebetween, among the plurality of word lines WL, may constitute one conductive line group CLG. According to embodiments, a plurality of conductive line groups CLG may be arranged apart from each other in the first horizontal direction (the X direction) with a separation insulating pattern 124 therebetween above the plurality of conductive lines BL. For example, between each pair of the plurality of back gate electrodes BG, a pair of word lines WL that are apart from each other in the first horizontal direction (the X direction) with the separation insulating pattern 124 therebetween and belong to different conductive line groups CLG from each other may be arranged.

According to embodiments, each of the plurality of channel structures CHL may be arranged, above the conductive line BL corresponding thereto, among the plurality of conductive lines BL, between one back gate electrode BG and one word line WL that are adjacent to each other in the first horizontal direction (the X direction). According to embodiments, a pair of channel structures CHL may be arranged on both sides of each of the plurality of back gate electrodes BG in the first horizontal direction (the X direction), and a pair of word lines WL may be arranged apart from each of the plurality of back gate electrodes BG with the pair of channel structures CHL therebetween. For example, a channel structure CHL may be arranged on each side of the back gate electrode BG in the first horizontal direction (the X direction), and for each channel structure CHL, a word line WL may be arranged on a side thereof facing away from the back gate electrode BG in the first horizontal direction (the X direction).

According to embodiments, in each of the plurality of conductive line groups CLG, a plurality of pairs of channel structures CHL may cover both sidewalls of one back gate electrode BG in the first horizontal direction (the X direction) and may be arranged in the second horizontal direction (the Y direction). For example, each pair of the plurality of pairs of channel structures CHL may be arranged above the conductive line BL corresponding thereto, among the plurality of conductive lines BL, and may be arranged apart from each other in the second horizontal direction (the Y direction). In each of the plurality of conductive line groups CLG, a first word line WL among two word lines WL may cover a first group of channel structures CHL covering a first sidewall of the back gate electrode BG, among the plurality of pairs of channel structures CHL, and a second word line WL among the two word lines WL may cover a second group of channel structures CHL covering a second sidewall of the back gate electrode BG, which is opposite to the first sidewall of the back gate electrode BG, among the plurality of pairs of channel structures CHL. According to embodiments, each of the plurality of channel structures CHL may face one back gate electrode BG on one side in the first horizontal direction (the X direction) and may face one word line WL on the other side.

In some embodiments, each of the plurality of back gate electrodes BG may be formed of or include metal, conductive metal nitride, doped polysilicon, or a combination thereof. For example, each of the plurality of back gate electrodes BG may include Ti, TiN, Ta, TaN, Mo, Ru, W, WN, TiSiN, WSiN, doped polysilicon, or a combination thereof, but embodiments are not limited thereto. Each of the plurality of word lines WL may be formed of or include metal, conductive metal nitride, or a combination thereof. For example, each of the plurality of word lines WL may include Ti, TiN, Ta, TaN, Mo, Ru, W, WN, TiSiN, WSiN, or a combination thereof, but embodiments are not limited thereto.

According to embodiments, the semiconductor memory device 100 may include, in the memory cell area MCA, a plurality of back gate dielectric films 112 respectively covering sidewalls of each of the plurality of back gate electrodes BG in the first horizontal direction (the X direction). Each of the plurality of back gate dielectric films 112 may be arranged between one back gate electrode BG and one channel structure CHL adjacent thereto. For example, each of the plurality of back gate dielectric films 112 may be in contact with the back gate electrode BG and the channel structure CHL. Each of the plurality of back gate dielectric films 112 may include one end in contact with the plurality of conductive lines BL and another end in contact with some of the plurality of contact plugs 130 in the vertical direction (the Z direction). For example, each of the plurality of back gate dielectric films 112 may have a first surface 112U and a second surface 112L that are opposite to each other in the vertical direction (the Z direction), the first surface 112U may face the plurality of contact plugs 130, and the second surface 112L may face the plurality of conductive lines BL. For example, the first surface 112U of each of the plurality of back gate dielectric films 112 may include a portion in contact with the first conductive patterns 132 of some of the plurality of contact plugs 130. For example, the second surface 112L of each of the plurality of back gate dielectric films 112 may be in contact with the plurality of conductive lines BL.

According to embodiments, between a pair of channel structures CHL adjacent to each other, a first capping insulating pattern 116 may be arranged between the back gate electrode BG and the plurality of contact plugs 130. Between the pair of channel structures CHL adjacent to each other, a second capping insulating pattern 154 may be arranged between the back gate electrode BG and the conductive line BL. In some embodiments, the first capping insulating pattern 116, the back gate electrode BG, and the second capping insulating pattern 154 may be arranged to overlap each other in the vertical direction (the Z direction), and each of both sidewalls of each of the first capping insulating pattern 116, the back gate electrode BG, and the second capping insulating pattern 154 in the first horizontal direction (the X direction) may be in contact with the back gate dielectric film 112 and covered by the back gate dielectric film 112. The back gate electrode BG may be apart from the plurality of contact plugs 130 in the vertical direction (the Z direction) with the first capping insulating pattern 116 therebetween. The back gate electrode BG may be apart from the plurality of conductive lines BL in the vertical direction (the Z direction) with the second capping insulating pattern 154 therebetween. In some embodiments, each of the first capping insulating pattern 116 and the second capping insulating pattern 154 may be formed of or include a silicon oxide film, a silicon nitride film, or a combination thereof.

According to embodiments, the semiconductor memory device 100 may include, in the memory cell area MCA, a plurality of gate dielectric films 122 respectively arranged between the plurality of word lines WL and the plurality of channel structures CHL adjacent thereto. A pair of gate dielectric films 122 may be arranged between a pair of channel structures CHL that are apart from each other with the separation insulating pattern 124 therebetween and adjacent to each other in the first horizontal direction (the X direction). A pair of word lines WL may be arranged between the pair of gate dielectric films 122. Each of the pair of gate dielectric films 122 may be arranged between one word line WL and the channel structures CHL that are arranged adjacent to the word line WL in the second horizontal direction (the Y direction), among the plurality of channel structures CHL, and may be in contact with the word line WL and the channel structures CHL. Each of the pair of gate dielectric films 122 may include one end in contact with the plurality of conductive lines BL and another end in contact with some of the plurality of contact plugs 130. For example, the gate dielectric film 122 may have a first surface 122U and a second surface 122L that are opposite to each other in the vertical direction (the Z direction), the first surface 122U may face the plurality of contact plugs 130, and the second surface 122L may face the plurality of conductive lines BL. For example, the first surface 122U of the gate dielectric film 122 may include a portion in contact with the first conductive patterns 132 of some of the plurality of contact plugs 130. For example, the second surface 122L of the gate dielectric film 122 may be in contact with the plurality of conductive lines BL.

According to embodiments, one sidewall of each of the plurality of channel structures CHL in the first horizontal direction (the X direction) may be in contact with one of the plurality of back gate dielectric films 112, and the other sidewall thereof may be in contact with one of the plurality of gate dielectric films 122. According to embodiments, each of both sidewalls of each of the plurality of channel structures CHL in the second horizontal direction (the Y direction) may be in contact with the gate dielectric film 122 corresponding thereto, among the plurality of gate dielectric films 122, and may face the word line WL corresponding thereto, among the plurality of word lines WL, with the gate dielectric film 122 therebetween (see, e.g., FIG. 2).

According to embodiments, the separation insulating pattern 124 may be arranged between a pair of word lines WL arranged between a pair of channel structures CHL adjacent to each other. A first buried insulating pattern 128 may be arranged between the pair of word lines WL and the plurality of contact plugs 130 in the vertical direction (the Z direction), and a pair of second buried insulating patterns 152 may be arranged between the pair of word lines WL and the conductive line BL in the vertical direction (the Z direction). The pair of second buried insulating patterns 152 may be apart from each other in the first horizontal direction (the X direction) with the separation insulating pattern 124 therebetween. Between the pair of channel structures CHL adjacent to each other, the pair of word lines WL, the first buried insulating pattern 128, and the pair of second buried insulating patterns 152 may be arranged to overlap each other in the vertical direction (the Z direction). The pair of word lines WL may be apart from the plurality of contact plugs 130 in the vertical direction (the Z direction) with the first buried insulating pattern 128 therebetween. The pair of word lines WL may be apart from the plurality of conductive lines BL with the pair of second buried insulating patterns 152 therebetween. In some embodiments, each of the separation insulating pattern 124, the first buried insulating pattern 128, and the second buried insulating pattern 152 may be formed of or include a silicon oxide film, a silicon nitride film, or a combination thereof.

According to embodiments, each of the gate dielectric film 122 and the back gate dielectric film 112 may be formed of or include a silicon oxide film, a high dielectric film, or a combination thereof. The high dielectric film refers to a film having a higher dielectric constant than a silicon oxide film. In embodiments, each of the gate dielectric film 122 and the back gate dielectric film 112 may include at least one material selected from silicon oxide, hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and lead scandium tantalum oxide (PbScTaO). The plurality of back gate electrodes BG, the plurality of word lines WL, the plurality of channel structures CHL, the plurality of back gate dielectric films 112, and the plurality of gate dielectric films 122, which are arranged between the plurality of conductive lines BL and the plurality of contact plugs 130, may constitute a plurality of vertical channel transistors CTR. Herein, the plurality of vertical channel transistors CTR may be referred to as a vertical channel transistor structure.

FIG. 3A illustrates that upper surfaces of the plurality of back gate electrodes BG are arranged closer to the plurality of conductive lines BL than upper surfaces of the plurality of word lines WL, but the inventive concept is not limited thereto. For example, the upper surfaces of the plurality of back gate electrodes BG may be arranged at the same vertical level as the upper surfaces of the plurality of word lines WL or may be arranged closer to the plurality of contact plugs 130 than the upper surfaces of the plurality of word lines WL.

As illustrated in FIG. 3A, a capacitor structure 140 may be arranged above the plurality of contact plugs 130 and the second interlayer insulating layer 138. The capacitor structure 140 may include a plurality of lower electrodes 142, a capacitor dielectric film 144 conformally covering a surface of each of the plurality of lower electrodes 142, and an upper electrode 146 covering the plurality of lower electrodes 142 with the capacitor dielectric film 144 therebetween. In some embodiments, the plurality of lower electrodes 142 may be arranged in the memory cell area MCA, and each of the plurality of lower electrodes 142 may be connected to the channel structure CHL through one contact plug 130 of the plurality of contact plugs 130. The third conductive pattern 136 included in each of the plurality of contact plugs 130 may function as a landing pad in contact with one lower electrode 142 of the plurality of lower electrodes 142. In some embodiments, the capacitor dielectric film 144 and the upper electrode 146 may include first portions covering the plurality of lower electrodes 142 in the memory cell area MCA and second portions arranged above the second interlayer insulating layer 138 in the interface area IA. For example, in the interface area IA, the second portions of the capacitor dielectric film 144 and the upper electrode 146 may be sequentially stacked above the second interlayer insulating layer 138. For example, the second portions may vertically overlap a first insulating block 104 and a second insulating block 106, which are described below. In some embodiments, the second portion of upper electrode 146 may be covered by an upper insulating layer 168. For example, the upper insulating layer 168 may be formed of or include a silicon oxide film, a silicon nitride film, or a combination thereof, but embodiments are not limited to the above examples.

In some embodiments, the capacitor dielectric film 144 may include a high dielectric film. The term “high dielectric film” as used herein refers to a dielectric film having a higher dielectric constant than a silicon oxide film. In some embodiments, the capacitor dielectric film 144 may be formed of or include metal oxide including at least one metal selected from hafnium (Hf), zirconium (Zr), aluminum (Al), niobium (Nb), cerium (Ce), lanthanum (La), tantalum (Ta), and titanium (Ti). In some embodiments, each of the plurality of lower electrodes 142 and the upper electrode 146 may be formed of or include a metal film, a conductive metal oxide film, a conductive metal nitride film, a conductive metal oxynitride film, or a combination thereof. In some embodiments, each of the plurality of lower electrodes 142 and the upper electrode 146 may include Nb, Nb oxide, Nb nitride, Nb oxynitride, Ti, Ti oxide, Ti nitride, Ti oxynitride, Co, Co oxide, Co nitride, Co oxynitride, Sn, Sn oxide, Sn nitride, Sn oxynitride, or a combination thereof. In some other embodiments, each of the plurality of lower electrodes 142 and the upper electrode 146 may include TaN, TiAlN, TaAlN, V, VN, Mo, MON, W, WN, Ru, RuO₂, Ir, IrO₂, Pt, PtO, SrRuO₃ (SRO), (Ba,Sr)RuO₃ (BSRO), CaRuO₃ (CRO), (La,Sr)CoO₃ (LSCO), or a combination thereof. However, constituent materials of each of the plurality of lower electrodes 142 and the upper electrode 146 are not limited to the above examples.

According to embodiments, the semiconductor memory device 100 may include a first insulating block 104 and a second insulating block 106, which are arranged in the interface area IA. The first insulating block 104 and the second insulating block 106 may surround the plurality of vertical channel transistors CTR between the first interlayer insulating layer 162 and the second interlayer insulating layer 138. For example, each of the first insulating block 104 and the second insulating block 106 may vertically overlap the first interlayer insulating layer 162 and the second interlayer insulating layer 138. According to embodiments, the first insulating block 104 may be arranged adjacent to the plurality of vertical channel transistors CTR, and the second insulating block 106 may be apart from the plurality of vertical channel transistors CTR in the horizontal direction (the X direction and/or the Y direction) with the first insulating block 104 therebetween. For example, in a plan view, the first insulating block 104 may surround the plurality of vertical channel transistors CTR, and the second insulating block 106 may surround the first insulating block 104. For example, in a plan view, the plurality of vertical channel transistors CTR may be arranged within an inner boundary of the first insulating block 104 and may be arranged apart from the second insulating block 106 with the first insulating block 104 therebetween. For example, in a plan view, each of the first insulating block 104 and the second insulating block 106 may have a closed ring shape. For example, each of the first insulating block 104 and the second insulating block 106 may have a thickness in the vertical direction (the Z direction) substantially equal to a thickness of the channel structure CHL in the vertical direction (the Z direction).

In some other embodiments, in the interface area IA, the first insulating block 104 may be arranged adjacent to one side of the memory cell area MCA. For example, the first insulating block 104 may face the plurality of vertical channel transistors CTR in the first horizontal direction (the X direction) on one side of the memory cell area MCA in the first horizontal direction (the X direction), and the second insulating block 106 may be apart from the plurality of vertical channel transistors CTR in the first horizontal direction (the X direction) with the first insulating block 104 therebetween.

According to embodiments, the first insulating block 104 may have a first sidewall 104S1 facing the plurality of vertical channel transistors CTR and a second sidewall 104S2 facing the second insulating block 106. FIG. 3A illustrates that a boundary channel structure CB, which is selected from the plurality of channel structures CHL and adjacent to an outer boundary of the memory cell area MCA, extends in the second horizontal direction (the Y direction), and that the first sidewall 104S1 is in contact with the boundary channel structure CB, but embodiments are not limited thereto. For example, a single insulating layer or multiple insulating layers may be arranged between the boundary channel structure CB and the first insulating block 104. Also, the boundary channel structure CB is illustrated as having the same thickness in the first horizontal direction (the X direction) as the other channel structures CHL, but embodiments are not limited thereto. For example, the boundary channel structure CB may be a dummy channel structure and may have a greater thickness in the first horizontal direction (the X direction) than the other channel structures CHL.

According to embodiments, the first insulating block 104 may include a first surface 104U and a second surface 104L that are opposite to each other in the vertical direction (the Z direction). The first surface 104U may be in contact with the second interlayer insulating layer 138, and the second surface 104L may be in contact with the first interlayer insulating layer 162. In some embodiments, the second insulating block 106 may include a first surface 106U and a second surface 106L that are opposite to each other in the vertical direction (the Z direction). The first surface 106U may be in contact with the second interlayer insulating layer 138, and the second surface 106L may be in contact with the first interlayer insulating layer 162.

In some embodiments, the second surface 104L of the first insulating block 104 may include a portion in contact with the plurality of conductive lines BL. The first insulating block 104 may overlap portions of the plurality of conductive lines BL in the vertical direction (the Z direction).

In some embodiments, the upper electrode 146 and the capacitor dielectric film 144 may include portions facing the first surface 104U of the first insulating block 104 and the first surface 106U of the second insulating block 106 in the interface area IA. The upper electrode 146 and the capacitor dielectric film 144 may vertically overlap the first insulating block 104 and the second insulating block 106 in the interface area IA.

In some embodiments, the first insulating block 104 and the second insulating block 106 may include different materials from each other. For example, the first insulating block 104 and the second insulating block 106 may have different removal rates from each other during an etching process, a polishing process, etc. for manufacturing the semiconductor memory device 100. In some embodiments, the first insulating block 104 may be formed of or include a silicon oxide film, and the second insulating block 106 may be formed of or include a silicon nitride film. The first insulating block 104 may be formed of a single, continuous material and the second insulating block 106 may be formed of a different single, continuous material.

In some embodiments, each of the first interlayer insulating layer 162 and the second interlayer insulating layer 138 may include the same material as the second insulating block 106. Although not illustrated, a capacitor contact (not illustrated) connecting a peripheral circuit transistor (not illustrated) and the upper electrode 146 to each other may be arranged in the interface area IA. The second insulating block 106, the first interlayer insulating layer 162, and the second interlayer insulating layer 138 may include the same material, so that a contact hole (not illustrated) penetrating the second insulating block 106, the first interlayer insulating layer 162, and the second interlayer insulating layer 138 may be formed in a single step without changing an etchant.

In some embodiments, the first surface 104U of the first insulating block 104 and the first surface 106U of the second insulating block 106 may be arranged on a first plane, and the first surfaces 112U of the plurality of back gate dielectric films 112 and the first surfaces 122U of the plurality of gate dielectric films 122 may be arranged on the first plane. For example, the first surface 104U of the first insulating block 104, the first surface 106U of the second insulating block 106, the first surfaces 112U of the plurality of back gate dielectric films 112, and the first surfaces 122U of the plurality of gate dielectric films 122 may be arranged on the same plane. In some embodiments, an upper surface of the first buried insulating pattern 128 and an upper surface of the first capping insulating pattern 116 may be arranged on the first plane.

In some embodiments, the second surface 104L of the first insulating block 104 and the second surface 106L of the second insulating block 106 may be arranged on the same plane (e.g., may be coplanar), for example, on a second plane. The second surface 106L of the second insulating block 106 may function as a grinding stopper in a polishing process for manufacturing the semiconductor memory device 100, and the second surfaces 112L of the plurality of back gate dielectric films 112 and the second surfaces 122L of the plurality of gate dielectric films 122 may be arranged on the same plane as the second surface 106L of the second insulating block 106. In some embodiments, a lower surface of the second buried insulating pattern 152 and a lower surface of the second capping insulating pattern 154 may be arranged on the second plane.

It will be appreciated that “coplanar,” “same plane”, etc., as used herein refer to structures (e.g., surfaces) that need not be perfectly geometrically planar, but may include acceptable variances that may result from standard manufacturing processes.

In some embodiments, the first sidewall 104S1 of the first insulating block 104 may face the plurality of vertical channel transistors CTR and may extend linearly in the vertical direction (the Z direction). In some embodiments, the second sidewall 104S2 of the first insulating block 104 may face the second insulating block 106 and may include a first portion S2A that extends linearly and a second portion S2B that is rounded. The first portion S2A may be arranged closer to the plurality of contact plugs 130 than the second portion S2B. The second portion S2B may extend from the first portion S2A and may extend such that a distance from the plurality of vertical channel transistors CTR to the second portion S2B in the horizontal direction (the X direction and/or the Y direction) increases toward the first interlayer insulating layer 162. In some embodiments, the second portion S2B may extend such that a horizontal distance from the first sidewall 104S1 to the second portion S2B increases toward the second surface 104L.

In some embodiments, the first insulating block 104 may include an upper portion 104A in contact with the second interlayer insulating layer 138 and a lower portion 104B that extends from the upper portion 104A and has a greater width in the horizontal direction (e.g., the first horizontal direction (the X direction)) than the upper portion 104A. The lower portion 104B may be in contact with the first interlayer insulating layer 162. For example, the first portion S2A of the second sidewall 104S2 may be a sidewall of the upper portion 104A, and the second portion S2B of the second sidewall 104S2 may be a sidewall of the lower portion 104B. In some embodiments, the upper portion 104A of the first insulating block 104 may have a uniform width in the first horizontal direction (the X direction) regardless of a vertical level. The lower portion 104B of the first insulating block 104 may have a greater width in the first horizontal direction (the X direction) toward the first interlayer insulating layer 162. In some embodiments, the lower portion 104B of the first insulating block 104 may include a protrusion PP protruding from the first portion S2A of the second sidewall 104S2. For example, a sidewall of the protrusion PP may constitute the second portion S2B of the second sidewall 104S2. In some embodiments, the protrusion PP may vertically overlap the second insulating block 106 in the vertical direction and may be in contact with the first interlayer insulating layer 162 at a lower surface of the protrusion PP. For example, the protrusion PP may be arranged between the first interlayer insulating layer 162 and the second insulating block 106 in the vertical direction (the Z direction). For example, a lower edge of the second insulating block 106 extending in the second horizontal direction (the Y direction) may be a rounded edge and a portion of the first insulating block 104 may extend or protrude underneath the rounded edge of the second insulating block 106.

In some embodiments, a sidewall of the second insulating block 106, which faces the first insulating block 104, may have a profile corresponding to the second sidewall 104S2 of the first insulating block 104. For example, the sidewall of the second insulating block 106 may include a first portion that extends linearly and a second portion that is rounded, and the second portion may face the protrusion PP of the first insulating block 104.

The semiconductor memory device 100 according to embodiments includes the first insulating block 104 that is adjacent to the plurality of vertical channel transistors CTR in the interface area IA, and the second insulating block 106 that is apart from the plurality of vertical channel transistors CTR with the first insulating block 104 therebetween, and the first insulating block 104 and the second insulating block 106 include different materials from each other. In an operation of separating the plurality of channel structures CHL during a manufacturing process of the semiconductor memory device 100, the second surface 106L of the second insulating block 106 may be used as a grinding stopper. Unlike a semiconductor memory device according to a comparative example, which is manufactured on a high-cost silicon on insulator (SOI) substrate, the semiconductor memory device 100 according to embodiments may be manufactured based on a substrate in which a separate insulating layer is omitted. Accordingly, the semiconductor memory device 100 having excellent reliability may be manufactured at relatively low costs.

FIG. 4 is a perspective view of a semiconductor memory device 500 according to some other embodiments. FIG. 5 is a cross-sectional view of the semiconductor memory device 500 according to some other embodiments. In detail, a plan layout diagram of a region “EX2” in FIG. 4 may correspond to a region “EX1” in FIG. 1, and FIG. 5 may be a cross-sectional view of a region corresponding to a cross-section taken along line X1-X1′ of FIG. 2. In FIGS. 4 and 5, the same reference numerals as those in FIGS. 1 to 3B denote the same components, and redundant descriptions thereof are omitted.

Referring to FIG. 4, the semiconductor memory device 500 may include a cell array structure CAS and a peripheral circuit structure PCS that overlap each other in the vertical direction (the Z direction). The cell array structure CAS may include the memory cell area MCA in which the plurality of memory cells including the plurality of vertical channel transistors CTR are arranged.

According to embodiments, the semiconductor memory device 500 may have a chip to chip (C2C) structure. The C2C structure may be obtained by forming the cell array structure CAS on a first wafer, forming the peripheral circuit structure PCS on a second wafer that is different from the first wafer, and then connecting the cell array structure CAS and the peripheral circuit structure PCS to each other by a bonding method. For example, the bonding method may refer to a method of bonding a plurality of first bonding metal pads 178A formed on a lowest metal layer of the cell array structure CAS to a plurality of second bonding metal pads 178B formed on an uppermost metal layer of the peripheral circuit structure PCS so as to be electrically connected to each other. In embodiments, when the plurality of first bonding metal pads 178A and the plurality of second bonding metal pads 178B include copper (Cu), the bonding method may be a Cu—Cu bonding method. In other embodiments, each of the plurality of first bonding metal pads 178A and the plurality of second bonding metal pads 178B may be formed of or include aluminum (Al) or tungsten (W).

The cell array structure CAS has substantially the same configuration as the semiconductor memory device 100 described with reference to FIGS. 1 to 3B. However, the cell array structure CAS includes a first wiring structure MS arranged between the plurality of conductive lines BL and the first interlayer insulating layer 162, and the peripheral circuit structure PCS.

According to embodiments, the first wiring structure MS may include a plurality of first conductive lines 172, a plurality of first contact plugs 174, a first insulating layer 176, and the plurality of first bonding metal pads 178A. For example, the plurality of first conductive lines 172 may be arranged at different vertical levels from each other, and the plurality of first contact plugs 174 may extend in the vertical direction (the Z direction) and may connect between a pair of first conductive lines 172 adjacent to each other and between the plurality of first conductive lines 172 and the plurality of conductive lines BL. The first insulating layer 176 may surround the plurality of first conductive lines 172, the plurality of first contact plugs 174, and the plurality of first bonding metal pads 178A. In some embodiments, the first insulating layer 176 may be formed of or include a silicon oxide film, a silicon nitride film, a SiON film, a SiOCN film, or a combination thereof. Herein, the first wiring structure MS may be referred to as an upper wiring structure.

According to embodiments, the semiconductor memory device 500 may include a capacitor contact 180 that penetrates at least a portion of the first insulating layer 176, the first interlayer insulating layer 162, the second insulating block 106, the second interlayer insulating layer 138, and the capacitor dielectric film 144 and is in contact with the upper electrode 146. In some embodiments, one end of the capacitor contact 180 may be in contact with and connected to some of the plurality of first conductive lines 172, and the other end thereof may be in contact with and connected to the upper electrode 146.

In some embodiments, the first insulating layer 176, the first interlayer insulating layer 162, the second insulating block 106, and the second interlayer insulating layer 138 may include the same material, and the first insulating block 104 may include a different material from the first insulating layer 176, the first interlayer insulating layer 162, the second insulating block 106, and the second interlayer insulating layer 138. For example, the first insulating layer 176, the first interlayer insulating layer 162, the second insulating block 106, and the second interlayer insulating layer 138 may be formed of or include a silicon nitride film, and the first insulating block 104 may be formed of or include a silicon oxide film.

In some embodiments, each of the plurality of first conductive lines 172, the plurality of first contact plugs 174, and the capacitor contact 180 may be formed of or include tungsten, titanium, tantalum, copper, aluminum, titanium nitride, tantalum nitride, tungsten nitride, or a combination thereof.

According to embodiments, the peripheral circuit structure PCS may include a substrate 52, a plurality of circuits formed on the substrate 52, and a second wiring structure MWS for connecting the plurality of circuits to each other or connecting the plurality of circuits to components in the memory cell area MCA of the cell array structure CAS.

In some embodiments, the substrate 52 may include a semiconductor substrate. For example, the substrate 52 may be formed of or include Si, Ge, or SiGe. An active region AC may be defined in the substrate 52 by a device separation film 54. A plurality of peripheral circuit transistors PTR constituting a plurality of circuits may be formed on the active region AC. Each of the plurality of peripheral circuit transistors PTR may include a gate dielectric film 62 and a gate 64 that are sequentially stacked on the substrate 52 and a plurality of ion implantation regions 66 that are formed in the active region AC on both sides of the gate 64. Each of the plurality of ion implantation regions 66 may constitute a source region or a drain region of a transistor PTR.

In some embodiments, the second wiring structure MWS included in the peripheral circuit structure PCS may include a plurality of second contact plugs 72, a plurality of second conductive lines 74, the plurality of second bonding metal pads 178B, and a second insulating layer 76. The second insulating layer 76 may surround the plurality of second contact plugs 72, the plurality of second conductive lines 74, and the plurality of second bonding metal pads 178B. At least some of the plurality of second conductive lines 74 may be configured to be electrically connected to the peripheral circuit transistor PTR. The plurality of second contact plugs 72 may be configured to connect the plurality of peripheral circuit transistors PTR and some selected from the plurality of second conductive lines 74 to each other. Each of the plurality of peripheral circuit transistors PTR may be configured to be electrically connected to the memory cell area MCA through the first wiring structure MS and the second wiring structure MWS. For example, some of the plurality of peripheral circuit transistors PTR may be connected to at least one of the conductive line BL, the word line WL, and the back gate electrode BG through the first wiring structure MS and the second wiring structure MWS. Some other of the plurality of peripheral circuit transistors PTR may be connected to a capacitor structure 140 through the first wiring structure MS, the second wiring structure MWS, and the capacitor contact 180. Herein, the second wiring structure MWS may be referred to as a lower wiring structure.

In some embodiments, each of the plurality of second contact plugs 72 and the plurality of second conductive lines 74 in the peripheral circuit structure PCS may be formed of or include tungsten, aluminum, copper, or a combination thereof, but embodiments are not limited thereto. In some embodiments, the second insulating layer 76 may include a single film or multiple films. In some embodiments, the second insulating layer 76 may be formed of or include a silicon oxide film, a silicon nitride film, a SiON film, a SiOCN film, or a combination thereof.

The plurality of second bonding metal pads 178B may be configured to be bonded to the plurality of first bonding metal pads 178A included in the cell array structure CAS and be electrically connected to the plurality of first bonding metal pads 178A. The plurality of first bonding metal pads 178A and the plurality of second bonding metal pads 178B may constitute a plurality of bonding structures BS. The plurality of conductive lines BL may be configured to be connected to at least one circuit selected from the plurality of circuits included in the peripheral circuit structure PCS through the bonding structure BS including the first bonding metal pad 178A and the second bonding metal pad 178B. In some embodiments, each of the plurality of first bonding metal pads 178A and the plurality of second bonding metal pads 178B constituting the bonding structure BS may be formed of or include copper, aluminum, or tungsten.

Hereinafter, a method of manufacturing a semiconductor memory device, according to embodiments, will be described with detailed examples.

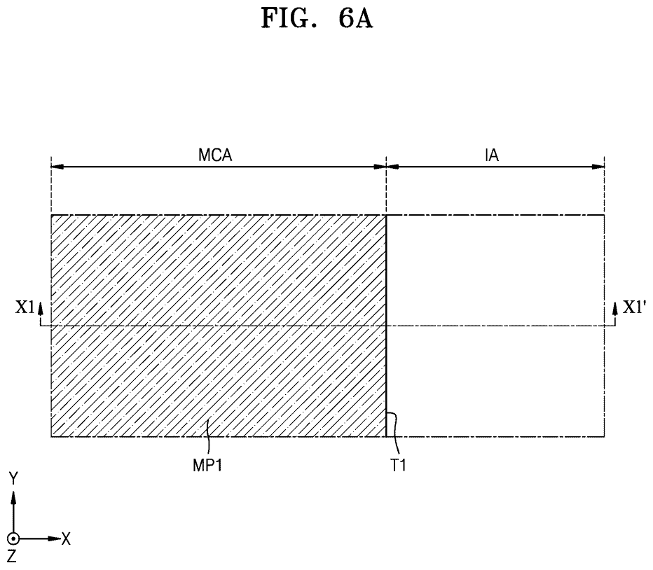

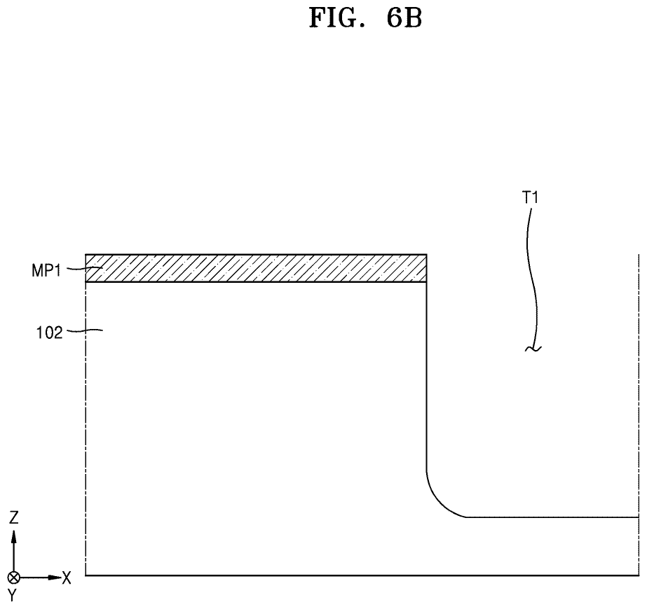

FIGS. 6A to 15 are diagrams illustrating a process sequence of a method of manufacturing a semiconductor memory device, according to embodiments, wherein FIGS. 6A, 8A, 10A, 11A, and 12A are plan layout diagrams of some components according to the process sequence of the method of manufacturing a semiconductor memory device, and FIGS. 6B, 7, 8B, 9, 10B, 11B, 12B, 13, 14, and 15 are cross-sectional views of a region corresponding to the line X1-X1′ in FIG. 2, according to the process sequence. An example method of manufacturing the semiconductor memory device 100 illustrated in FIGS. 1 to 3B will be described with reference to FIGS. 6A to 15. In FIGS. 6A to 15, the same reference numerals as those in FIGS. 1 to 3B denote the same components, and redundant descriptions thereof are omitted.

Referring to FIGS. 6A and 6B, a semiconductor substrate 102 may be prepared. In some embodiments, the semiconductor substrate 102 may be a bulk substrate that does not include an insulating layer, rather than an SOI substrate. In some embodiments, the semiconductor substrate 102 may include silicon, for example, single crystalline silicon, polycrystalline silicon, or amorphous silicon. In some embodiments, the semiconductor substrate 102 may include at least one selected from Ge, SiGe, SiC, GaAs, InAs, and InP. In some embodiments, the semiconductor substrate 102 may include an impurity-doped well or an impurity-doped structure.

A first mask pattern MP1 may be formed on the semiconductor substrate 102. The first mask pattern MP1 may cover the memory cell area MCA of the semiconductor substrate 102, in which the vertical channel transistors CTR described with reference to FIGS. 1 to 3B are formed, and the semiconductor substrate 102 in the interface area IA may be exposed by the first mask pattern MP1. In some embodiments, the first mask pattern MP1 may include a photoresist film, a SiOC film, and a SiOCN film, but embodiments are not limited to the above examples.

According to embodiments, a first trench T1 may be formed by removing a partial region of the semiconductor substrate 102 by using the first mask pattern MP1 as an etch mask. In some embodiments, the first trench T1 may be formed to surround the memory cell area MCA.

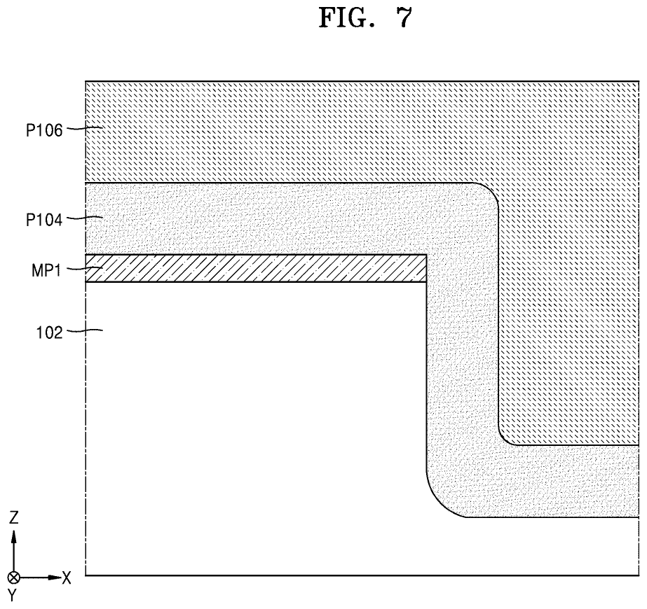

Referring to FIG. 7, in the result of FIGS. 6A and 6B, a first preliminary insulating layer P104 conformally covering a surface of each of an inner wall of the first trench T1 and the first mask pattern MP1, and a second preliminary insulating layer P106 filling the first trench T1 on the first preliminary insulating layer P104 may be formed. In some embodiments, a lower surface and an inner side wall of the first trench T1 may meet in a curved surface, rather than meeting vertically, and the first preliminary insulating layer P104 may have a profile corresponding to curved meeting between the lower surface and the inner side wall of the first trench T1.

In some embodiments, the first preliminary insulating layer P104 and the second preliminary insulating layer P106 may be formed through an atomic layer deposition (ALD) process, a chemical vapor deposition (CVD) process, etc., but embodiments are not limited to the above examples.

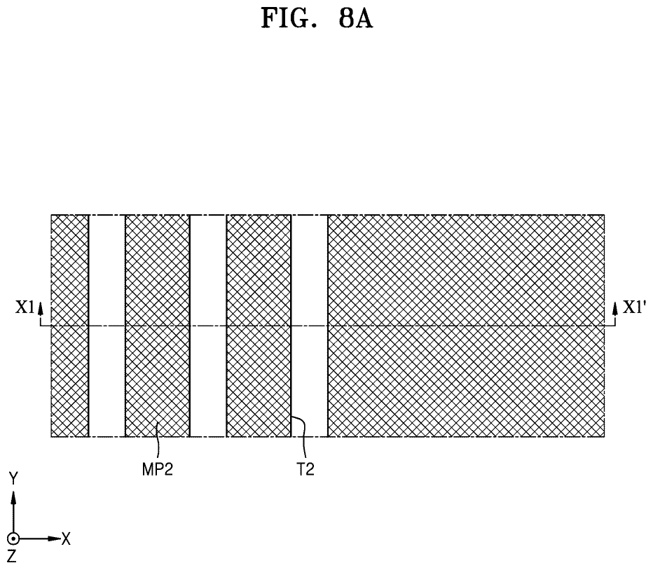

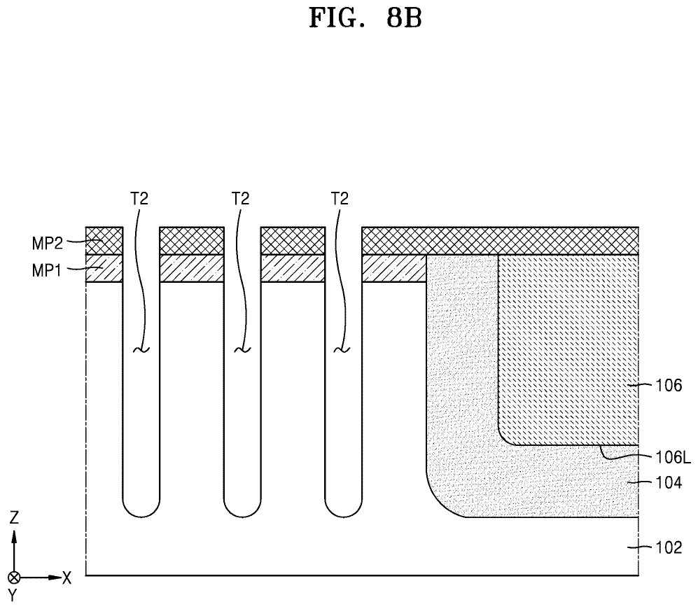

Referring to FIGS. 8A and 8B, in the result of FIG. 7, a first insulating block 104 and a second insulating block 106 may be formed by removing a portion of the first preliminary insulating layer P104 and a portion of the second preliminary insulating layer P106 until an upper surface of the first mask pattern MP1 is exposed.

In some embodiments, the first insulating block 104 and the second insulating block 106 may be formed by grinding the first preliminary insulating layer P104 and the second preliminary insulating layer P106 until the upper surface of the first mask pattern MP1 is exposed. In some other embodiments, the first insulating block 104 and the second insulating block 106 may be formed by etching back the first preliminary insulating layer P104 and the second preliminary insulating layer P106 until the upper surface of the first mask pattern MP1 is exposed.

Afterwards, a second mask pattern MP2 exposing the memory cell area MCA may be formed. By removing a portion of the first mask pattern MP1 and a portion of the semiconductor substrate 102 in the memory cell area MCA by using the second mask pattern MP2 as an etch mask, a plurality of second trenches T2 extending lengthwise in the second horizontal direction (the Y direction) may be formed in the memory cell area MCA.

In some embodiments, the second mask pattern MP2 may be formed of or include a silicon oxide film, a silicon nitride film, or a combination thereof, but embodiments are not limited to the above examples.

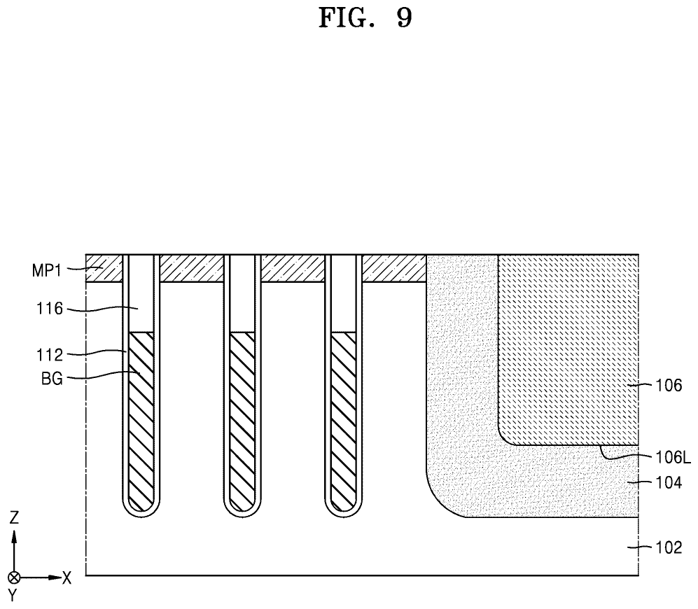

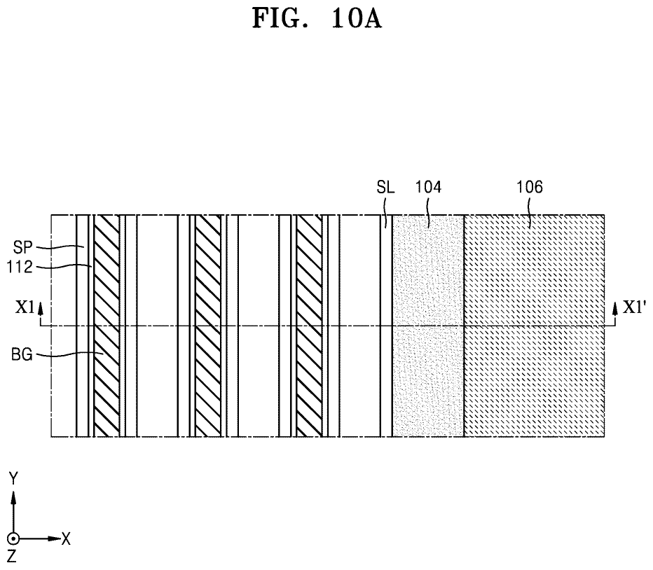

Referring to FIG. 9, in the result of FIGS. 8A and 8B, a back gate dielectric film 112 conformally covering a surface of each of inner walls of the plurality of second trenches T2 and the second mask pattern MP2, and a back gate electrode BG partially filling the plurality of second trenches T2 on the back gate dielectric film 112 may be formed. Afterwards, an upper space of each of the plurality of second trenches T2 may be filled with the first capping insulating pattern 116, and the obtained result may be planarized to expose the upper surface of the first mask pattern MP1. For example, the second mask pattern MP2 may be removed during the planarization process.

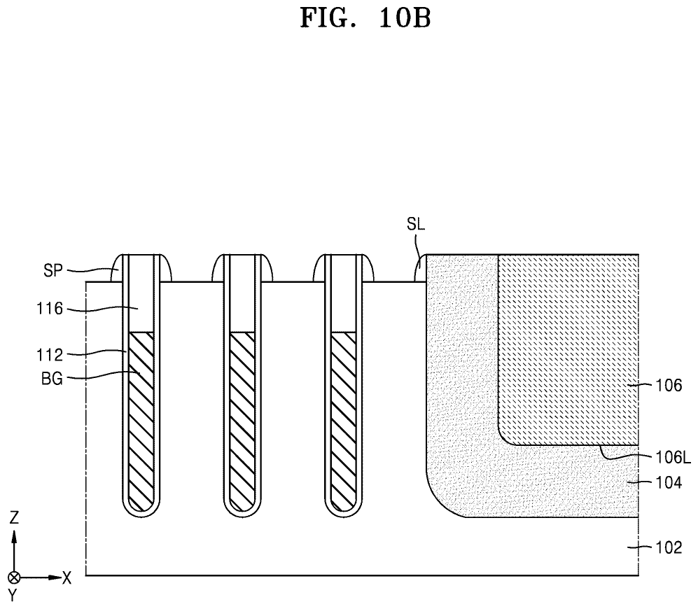

Referring to FIGS. 10A and 10B, the first mask pattern MP1 may be removed from the result of FIG. 9, and an upper surface of the semiconductor substrate 102 may be exposed.

Afterwards, a plurality of spacer lines SL respectively arranged on a sidewall of the back gate dielectric film 112 and a sidewall of the first insulating block 104 on the semiconductor substrate 102 may be formed. The plurality of spacer lines SL may be formed in a self-aligned manner on the sidewall of the back gate dielectric film 112 and the sidewall of the first insulating block 104 on the upper surface of the semiconductor substrate 102. For example, an insulating layer covering the result of FIG. 9 may be formed, and an anisotropic etching process may be performed until the first capping insulating pattern 116 is exposed to form a plurality of spacer lines SL extending lengthwise in the second horizontal direction (the Y direction) along the sidewall of the back gate dielectric film 112. In a plan view, the plurality of spacer lines SL may be arranged to surround the back gate electrode BG and the back gate dielectric film 112. In some embodiments, the plurality of spacer lines SL may be formed of or include a silicon oxide film, a silicon nitride film, or a combination thereof, but embodiments are not limited to the above examples.

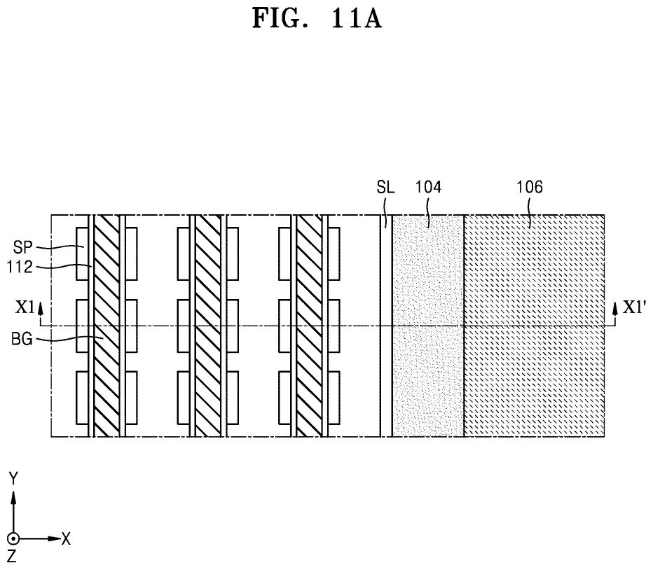

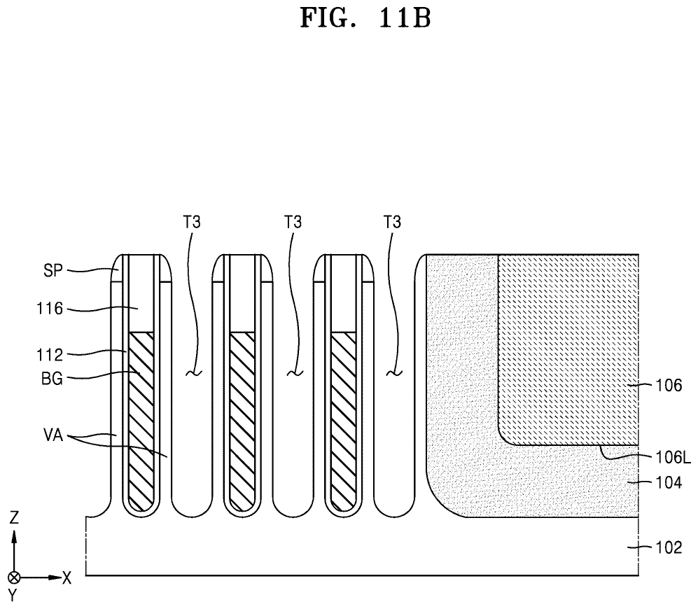

Referring to FIGS. 11A and 11B, in the result of FIGS. 10A and 10B, an additional mask pattern (not illustrated) in the shape of a line pattern extending lengthwise in the first horizontal direction (the X direction) may be formed in the memory cell area MCA, and a portion of the spacer line SL that is not covered by the additional mask pattern (not illustrated) may be removed to form a plurality of spacer patterns SP. For example, the plurality of spacer patterns SP may be arranged apart from each other in the second horizontal direction (the Y direction) on the sidewall of the back gate dielectric film 112. In some embodiments, as illustrated in FIG. 11A, one spacer line SL closest to the interface area IA in the first horizontal direction (the X direction), among the plurality of spacer lines SL, may remain without being removed by the additional mask pattern.

Afterwards, the semiconductor substrate 102 may be etched by using a plurality of first capping insulating patterns 116, a plurality of back gate dielectric films 112, and the plurality of spacer patterns SP as etch masks to form a plurality of third trenches T3. As a result, portions of the semiconductor substrate 102 that vertically overlap the plurality of spacer patterns SP may remain as a plurality of vertical active regions VA. For example, the plurality of vertical active regions VA may be arranged in a matrix arrangement to be apart from each other in the first horizontal direction (the X direction) and the second horizontal direction (the Y direction). A portion of the semiconductor substrate 102 that vertically overlaps the spacer line SL may extend in the second horizontal direction (the Y direction).

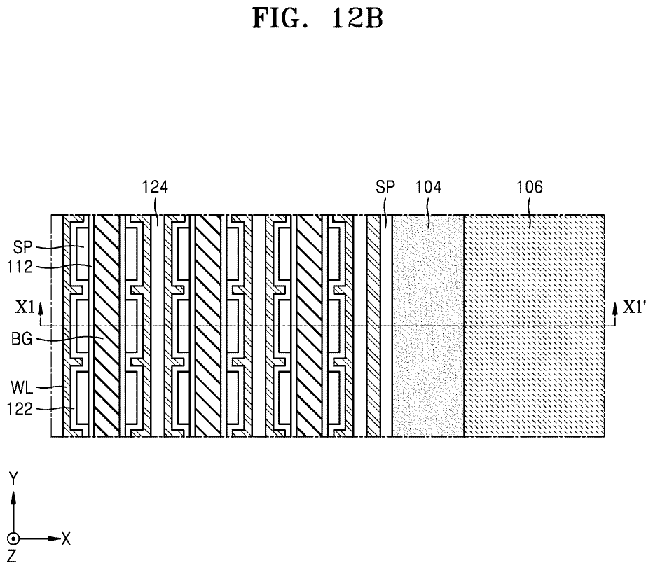

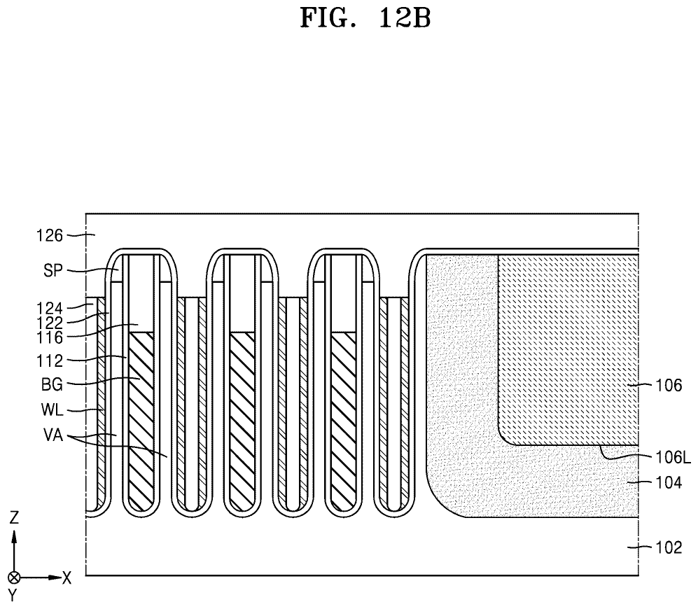

Referring to FIGS. 12A and 12B, a gate dielectric film 122 conformally covering the result of FIGS. 11A and 11B may be formed, a conductive layer conformally covering the gate dielectric film 122 may be formed, and then, a portion of the conductive layer may be etched to separate the conductive layer into a plurality of word lines WL. Afterwards, a separation insulating pattern 124 filling the third trench T3 may be formed between two word lines WL adjacent to each other.

Thereafter, an upper space of the third trench T3 may be provided by removing an upper portion of the separation insulating pattern 124 and upper portions of the plurality of word lines WL, and then, a first buried insulating layer 126 filling the upper space may be formed. Constituent materials of the first buried insulating layer 126 are as described above with respect to the constituent materials of the first buried insulating pattern 128.

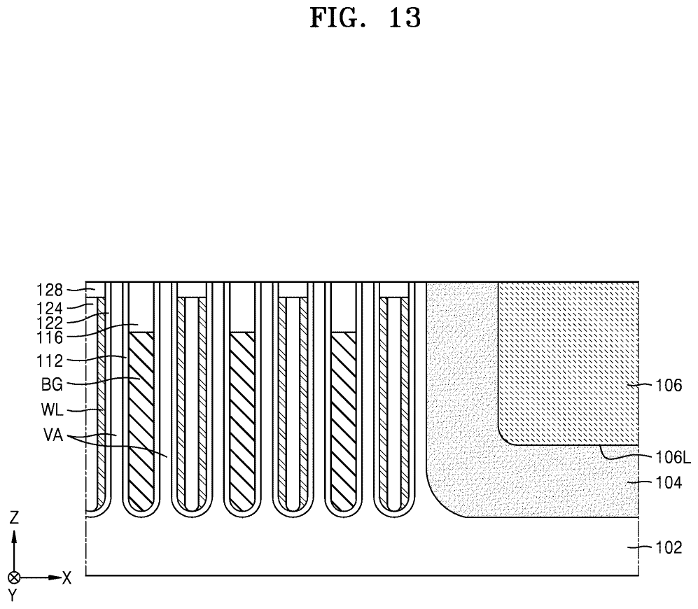

Referring to FIG. 13, in the result of FIGS. 12A and 12B, a planarization process may be performed on an exposed upper surface of the first buried insulating layer 126 to expose the plurality of vertical active regions VA, and a plurality of first buried insulating patterns 128 may be formed from the first buried insulating layer 126. As the planarization process is performed, the height of an uppermost portion of each of the back gate dielectric film 112, the first capping insulating pattern 116, the first insulating block 104, and the second insulating block 106 may be lowered.

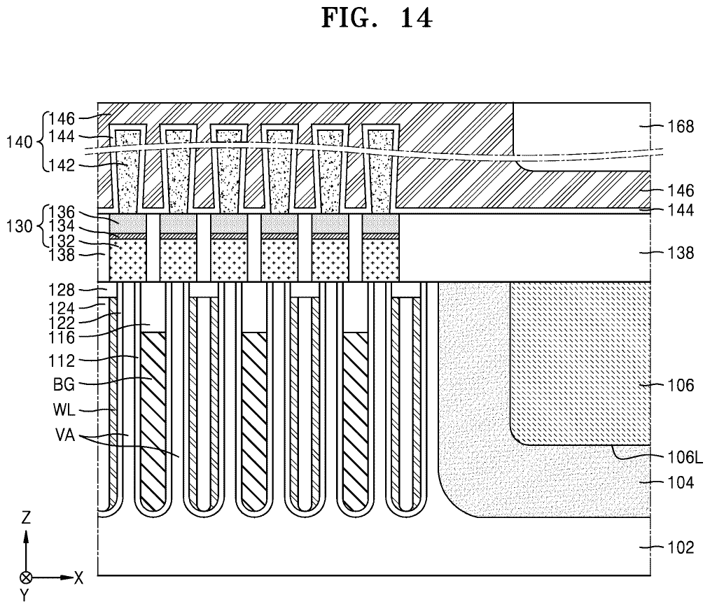

Referring to FIG. 14, in the result of FIG. 13, a plurality of contact plugs 130 may be formed on the plurality of vertical active regions VA, and a second interlayer insulating layer 138 filling a space between each pair of the plurality of contact plugs 130 may be formed.

Afterwards, a capacitor structure 140 connected to the plurality of contact plugs 130 may be formed on the plurality of contact plugs 130 and the second interlayer insulating layer 138.

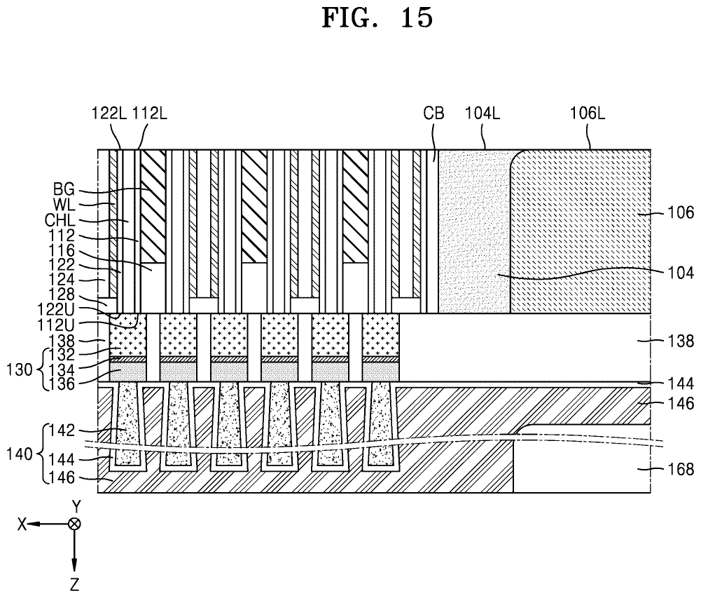

Referring to FIG. 15, in the result of FIG. 14, the result of FIG. 14 may be turned over such that directions of upper and lower portions thereof in the vertical direction (the Z direction) are reversed, so that the semiconductor substrate 102 faces upward in the vertical direction (the Z direction), and a grinding process and a wet etching process may be sequentially performed on the semiconductor substrate 102 until the second surface 106L of the second insulating block 106 is exposed.

As a portion of the semiconductor substrate 102 is removed, the plurality of vertical active regions VA may be separated so that a plurality of channel structures CHL are formed and exposed, and through the grinding process and the wet etching process, a portion of each of the plurality of back gate electrodes BG, the plurality of word lines WL, the plurality of back gate dielectric films 112, the plurality of gate dielectric films 122, and the separation insulating pattern 124 may be removed so that each of the plurality of back gate electrodes BG, the plurality of word lines WL, the plurality of back gate dielectric films 112, the plurality of gate dielectric films 122, and the separation insulating pattern 124 is exposed.

In a method of manufacturing the semiconductor memory device 100 according to embodiments, the second insulating block 106 may have a lower removal rate than the first insulating block 104 in the grinding process and may function as a grinding stop surface. Because the method of manufacturing the semiconductor memory device 100 according to embodiments does not use an SOI substrate including a separate insulating layer, the semiconductor memory device 100 having excellent reliability may be manufactured at reduced costs.

Referring to FIG. 15 and FIGS. 2 to 3B together, in the result of FIG. 15, a plurality of spaces may be provided by removing a portion of each of the plurality of back gate electrodes BG and the plurality of word lines WL that are exposed, and a plurality of second buried insulating patterns 152 and a plurality of second capping insulating patterns 154 that fill the plurality of spaces may be formed.

Afterwards, a plurality of conductive lines BL and a first interlayer insulating layer 162 that cover the plurality of back gate dielectric films 112, the plurality of gate dielectric films 122, the separation insulating pattern 124, the plurality of channel structures CHL, the plurality of second buried insulating patterns 152, and the plurality of second capping insulating patterns 154 may be formed to thereby manufacture the semiconductor memory device 100.

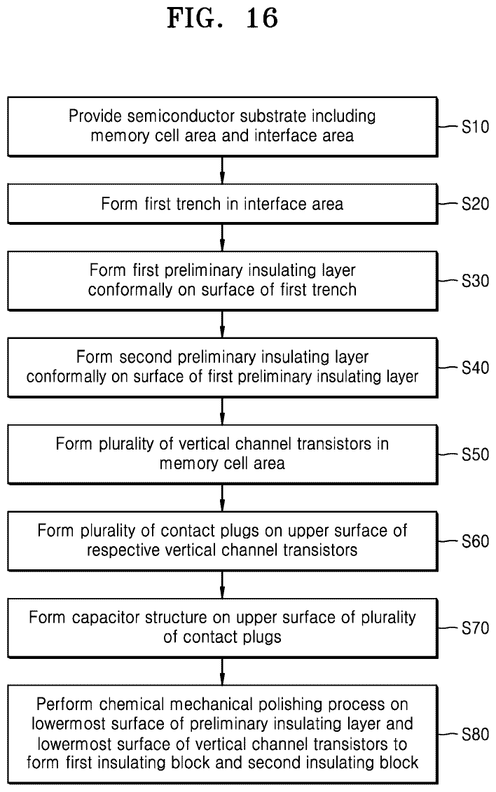

FIG. 16 shows a method of manufacturing a semiconductor device according to embodiments.

At step S10, a semiconductor substrate is provided including a memory cell area and an interface area.

At step S20, a trench T1 is formed in the interface area (see, e.g., FIG. 6B).

At step S30, a first preliminary insulating layer P104 is conformally formed on a surface of the trench.

At step S40, a second preliminary insulating layer P106 is conformally formed on a surface of the first preliminary insulating layer (see, e.g., FIG. 7).

At step S50, a plurality of vertical channel transistors are formed in the memory cell area of the semiconductor substrate (see, e.g., FIGS. 8A through 13).

At step S60, a plurality of contact plugs 130 are formed on an upper surface of respective vertical channel transistors (see, e.g., FIG. 14).

At step S70, a capacitor structure 140 is formed on an upper surface of the plurality of contact plugs (see, e.g., FIG. 14).

At step S80, a chemical mechanical polishing (CMP) process is performed on the lowermost surface of the second preliminary insulating layer and on the lowermost surface of the plurality of vertical channel transistors to form a first insulating block 104 and a second insulating block 106 on the interface area IA of the semiconductor substrate (see, e.g., FIG. 15).

Hereinbefore, an example method of manufacturing the semiconductor memory device 100 illustrated in FIGS. 1 to 3B has been described with reference to FIGS. 6A to 15. However, one of ordinary skill in the art will understand that various modifications and changes may be made to the method described with reference to FIGS. 6A to 15 within the scope of the inventive concept, thereby enabling the manufacture of semiconductor memory devices having various structures obtained by making various modifications and changes to the semiconductor memory device 100 illustrated in FIGS. 1 to 3B.

While the inventive concept has been particularly shown and described with reference to embodiments thereof, it will be understood that various changes in form and details may be made therein without departing from the spirit and scope of the disclosure.

1. A semiconductor memory device comprising:
a memory cell area comprising a plurality of vertical channel transistors;
an interface area surrounding the memory cell area in a plan view;
a first insulating block in the interface area, a side surface of the first insulating block facing the plurality of vertical channel transistors in a first horizontal direction; and
a second insulating block apart from the plurality of vertical channel transistors in the first horizontal direction with the first insulating block between the second insulating block and the plurality of vertical channel transistors, the second insulating block comprising a different material from the first insulating block.

2. The semiconductor memory device of claim 1, wherein, in a plan view, the second insulating block surrounds the plurality of vertical channel transistors with the first insulating block between the second insulating block and the plurality of vertical channel transistors.

3. The semiconductor memory device of claim 1, wherein a lower surface of the first insulating block is coplanar with a lower surface of the second insulating block.

4. The semiconductor memory device of claim 1, wherein the first insulating block comprises a first sidewall and a second sidewall, the first sidewall facing the plurality of vertical channel transistors in the first horizontal direction, and the second sidewall facing the second insulating block in the first horizontal direction,
wherein the first sidewall extends linearly, and
the second sidewall comprises a first portion and a second portion, the first portion extending linearly, and the second portion being rounded.

5. The semiconductor memory device of claim 4, wherein a lower surface of the first insulating block and a lower surface of the second insulating block are arranged on the same plane, and
a distance between the second portion of the second sidewall and the plurality of vertical channel transistors in the first horizontal direction increases toward the lower surface of the first insulating block.

6. The semiconductor memory device of claim 1, further comprising:
a plurality of conductive lines extending in the first horizontal direction below the plurality of vertical channel transistors across the memory cell area to the interface area; and
a first interlayer insulating layer surrounding the plurality of conductive lines and being in contact with the first insulating block and the second insulating block in the interface area.

7. The semiconductor memory device of claim 1, further comprising a capacitor structure above the plurality of vertical channel transistors, the first insulating block, and the second insulating block,
wherein the capacitor structure comprises:
a plurality of lower electrodes above the plurality of vertical channel transistors in the memory cell area, the plurality of lower electrodes extending in a vertical direction;
an upper electrode comprising a first portion and a second portion, the first portion covering the plurality of lower electrodes in the memory cell area, and the second portion being in the interface area; and
a capacitor dielectric film arranged between the plurality of lower electrodes and the upper electrode,
wherein the second portion of the upper electrode vertically overlaps the first insulating block and the second insulating block.

8. The semiconductor memory device of claim 7, further comprising:
a plurality of contact plugs respectively arranged between the plurality of lower electrodes and the plurality of vertical channel transistors in the memory cell area; and
a second interlayer insulating layer surrounding the plurality of contact plugs and comprising a portion between the upper electrode and the second insulating block.

9. The semiconductor memory device of claim 8, wherein the second interlayer insulating layer and the second insulating block comprise the same material.

10. The semiconductor memory device of claim 1, wherein the plurality of vertical channel transistors comprises:
a back gate electrode extending lengthwise in a second horizontal direction intersecting the first horizontal direction;
a first channel structure and a second channel structure respectively arranged on both sides of the back gate electrode in the first horizontal direction;
a word line apart from the back gate electrode in the first horizontal direction with the first channel structure between the word line and the back gate electrode;
a back gate dielectric film between the first channel structure and the back gate electrode; and
a gate dielectric film between the first channel structure and the word line,
wherein a lower surface of the back gate dielectric film, a lower surface of the gate dielectric film, and a lower surface of the second insulating block are arranged on the same plane.

11. A semiconductor memory device comprising:
a first interlayer structure comprising a plurality of conductive lines and a first interlayer insulating layer, the plurality of conductive lines extending lengthwise in a first horizontal direction and being apart from each other in a second horizontal direction perpendicular to the first horizontal direction, and the first interlayer insulating layer surrounding the plurality of conductive lines;
a second interlayer structure comprising a plurality of contact plugs and a second interlayer insulating layer, the plurality of contact plugs being arranged at positions apart from the plurality of conductive lines in a vertical direction, and the second interlayer insulating layer surrounding the plurality of contact plugs;
a plurality of vertical channel transistors comprising a plurality of channel structures between the first interlayer structure and the second interlayer structure, the plurality of channel structures each being in contact with one of the plurality of conductive lines and one of the plurality of contact plugs;
a first insulating block including a side surface facing the plurality of vertical channel transistors in the first horizontal direction between the first interlayer structure and the second interlayer structure; and
a second insulating block apart from the plurality of vertical channel transistors with the first insulating block between the second insulating block and the plurality of vertical channel transistors, the second insulating block vertically overlapping the first interlayer insulating layer and the second interlayer insulating layer.

12. The semiconductor memory device of claim 11, wherein the second insulating block comprises the same material as the first interlayer insulating layer and the second interlayer insulating layer, and the second insulating block comprises a different material from the first insulating block.

13. The semiconductor memory device of claim 11, wherein the first insulating block comprises:
an upper portion in contact with the second interlayer insulating layer, the upper portion having a constant width in the first horizontal direction regardless of a vertical level; and
a lower portion extending from the upper portion to be in contact with the first interlayer insulating layer, the lower portion having a greater width in the first horizontal direction toward the first interlayer insulating layer in the vertical direction.

14. The semiconductor memory device of claim 13, wherein the lower portion comprises a protrusion protruding from one sidewall of the upper portion, and
wherein the protrusion vertically overlaps the second insulating block and is in contact with the first interlayer insulating layer at a lower surface of the protrusion.

15. The semiconductor memory device of claim 11, wherein the plurality of vertical channel transistors further comprise:
a plurality of back gate electrodes extending in the second horizontal direction between the plurality of conductive lines and the plurality of contact plugs, the plurality of back gate electrodes being apart from each other in the first horizontal direction;
a plurality of word lines extending in the second horizontal direction between the plurality of conductive lines and the plurality of contact plugs, each of the plurality of word lines being apart from one of the plurality of channel structures and one of the plurality of back gate electrodes;
a back gate dielectric film between a first back gate electrode and a first channel structure, the first back gate electrode being one of the plurality of back gate electrodes, and the first channel structure being one of the plurality of channel structures; and
a gate dielectric film between a first word line and the first channel structure, the first word line being one of the plurality of word lines and apart from the first back gate electrode with the first channel structure between the first word line and the first back gate electrode,
wherein a lower surface of the back gate dielectric film, a lower surface of the gate dielectric film, and a lower surface of the second insulating block are arranged on the same plane.

16. The semiconductor memory device of claim 11, wherein, in a plan view, each of the first insulating block and the second insulating block has a closed ring shape surrounding the plurality of vertical channel transistors.

17. A semiconductor memory device comprising:
a substrate comprising a memory cell area and an interface area on at least one side of the memory cell area;
a plurality of peripheral circuit transistors on an upper surface of the substrate;
a wiring structure above the plurality of peripheral circuit transistors, the wiring structure comprising a plurality of first conductive lines, a plurality of first contact plugs, and an insulating layer surrounding the plurality of first conductive lines and the plurality of first contact plugs;
a first interlayer structure comprising a plurality of second conductive lines and a first interlayer insulating layer, the plurality of second conductive lines extending lengthwise in a first horizontal direction above the wiring structure and being apart from each other in a second horizontal direction perpendicular to the first horizontal direction, and the first interlayer insulating layer surrounding the plurality of second conductive lines;
a second interlayer structure comprising a plurality of second contact plugs and a second interlayer insulating layer, the plurality of second contact plugs being arranged at positions apart from the plurality of first conductive lines in a vertical direction, and the second interlayer insulating layer surrounding the plurality of second contact plugs;
a plurality of vertical channel transistors comprising a plurality of channel structures between the first interlayer structure and the second interlayer structure, the plurality of channel structures each being in contact with one of the plurality of first conductive lines and one of the plurality of second contact plugs;
a capacitor structure above the second interlayer structure and comprising a plurality of lower electrodes, an upper electrode, and a capacitor dielectric film, the plurality of lower electrodes respectively being above the plurality of channel structures, the upper electrode covering the plurality of lower electrodes and the second interlayer insulating layer, and the capacitor dielectric film being between the upper electrode, the plurality of lower electrodes, and the second interlayer insulating layer;
a first insulating block in the interface area and facing the plurality of vertical channel transistors in the first horizontal direction between the first interlayer structure and the second interlayer structure;
a second insulating block in the interface area, apart from the plurality of vertical channel transistors with the first insulating block between the second insulating block and the plurality of vertical channel transistors, the second insulating block vertically overlapping the first interlayer insulating layer and the second interlayer insulating layer; and
a capacitor contact penetrating at least a portion of the insulating layer, the first interlayer insulating layer, the second insulating block, the second interlayer insulating layer, and the capacitor dielectric film, the capacitor contact being in contact with some of the plurality of first conductive lines and the upper electrode.

18. The semiconductor memory device of claim 17, wherein the first insulating block comprises a first sidewall and a second sidewall, the first sidewall facing the plurality of vertical channel transistors in the first horizontal direction, and the second sidewall facing the second insulating block in the first horizontal direction,
wherein the first sidewall extends linearly, and
the second sidewall comprises a first portion and a second portion, the first portion extending linearly, and the second portion being rounded.

19. The semiconductor memory device of claim 17, wherein the second insulating block comprises the same material as the insulating layer, the first interlayer insulating layer, and the second interlayer insulating layer and comprises a different material from the first insulating block.

20. The semiconductor memory device of claim 17, wherein the plurality of vertical channel transistors further comprise:
a plurality of back gate electrodes extending in the second horizontal direction between the plurality of first conductive lines and the plurality of second contact plugs in the vertical direction, the plurality of back gate electrodes being apart from each other in the first horizontal direction;
a plurality of word lines extending in the second horizontal direction between the plurality of first conductive lines and the plurality of second contact plugs in the vertical direction, the plurality of word lines each being apart from one of the plurality of channel structures and one of the plurality of back gate electrodes;
a back gate dielectric film between a first back gate electrode and a first channel structure, the first back gate electrode being one of the plurality of back gate electrodes, and the first channel structure being selected from the plurality of channel structures; and
a gate dielectric film between a first word line and the first channel structure, the first word line being one of the plurality of word lines and apart from the first back gate electrode with the first channel structure the first word line and the first back gate electrode,
wherein a lower surface of the back gate dielectric film, a lower surface of the gate dielectric film, and a lower surface of the second insulating block are arranged on the same plane.

21-25. (canceled)
